(19) United States
(12) Patent Application Publication
(10) Pub. No.: US 2017/0175257 A1
(43) Pub. Date: Jun. 22, 2017

(54) APPARATUS FOR MANUFACTURING AN ADHESIVE-FREE GAS BARRIER FILM HAVING A CERAMIC BARRIER LAYER

(71) Applicant: FRESENIUS MEDICAL CARE DEUTSCHLAND GMBH, Bad Homburg (DE)

(72) Inventors: Dietmar HANSEL, Ottweiler (DE); Klaus HEILMANN, St. Wendel (DE); Thomas SCHULTE, Hanau (DE); Tobias PFEIL, Freisen (DE); Bjoern BREITER, St. lngbert (DE)

(21) Appl. No.: 15/395,979

(22) Filed: Dec. 30, 2016

Related U.S. Application Data
(62) Division of application No. 14/028,261, filed on Sep. 16, 2013, now abandoned.
(60) Provisional application No. 61/702,884, filed on Sep. 19, 2012.

(30) Foreign Application Priority Data
Sep. 19, 2012 (DE) 102012018525.1

(51) Int. Cl. C23C 14/56; C23C 14/22; B29C 71/04; B29C 47/00; C23C 14/10

(52) U.S. Cl. CPC C23C 14/562; B29C 47/0021; C23C 14/10; B29C 71/04; C23C 14/221; B29L 2007/008

(57) ABSTRACT

The present invention relates to an apparatus for manufacturing an adhesive-free gas barrier film comprising conveying means for conveying a film web; at least one first lock system for introducing the film web into a coating chamber of the apparatus; at least one first coating means by means of which the film web can be at least partially coated by depositing a barrier material in the coating chamber; and optionally at least one second lock system for expelling the film web out of the coating chamber; and at least one second coating means by means of which the coated film web can be at least partially coated by extrusion of a plastic melt.

The present invention relates to an apparatus for manufacturing an adhesive-free gas barrier film having a preferably ceramic barrier layer, to a method of manufacturing an adhesive-free gas barrier film having a preferably ceramic barrier layer, to a multilayer gas barrier film, to a use of an apparatus for manufacturing an adhesive-free gas barrier film as well as to a disposable.

Barrier layer films are required, for example, for packaging dialysis solutions buffered with bicarbonate which are increasingly being used both in peritoneal dialysis and in acute dialysis. Furthermore, these film types equipped with gas barrier layers are also used as containers for enteral and parenteral nutrient solutions.

In conventional processes for the ceramic coating of film webs, a carrier film wound onto a sleeve is placed into a coating plant which is subsequently evacuated. As is shown in DE 42 21 800, the film is unrolled in this coating plant, is led past a coating apparatus via different guide rollers and is spooled up to form a film wrap again within the plant. A film wrap is understood in this connection as the film wound or spooled onto a sleeve. The coating processes require an evacuation of the entire plant. Generally, ceramic barrier layers manufactured in this manner react sensitively without any further protective coating to external effects such as tensile stresses which effect a film stretching or to kink applications in which the film material is likewise stretched.

EP 0 640 474 A1 also discloses the manufacture of a film composite in which a ceramic layer is applied to a carrier film by means of sputtering. This is a process in which a substrate film ceramically coated by means of sputtering and the cover layer are connected with a film composite in a high-vacuum evaporation plant.

Ceramic or glass-type barrier layers demonstrate a brittle behavior in common material thicknesses so that film stretching can result in crack formation in the barrier layer. The consequence may be a substantial deterioration of the barrier effect. Carrier films are therefore usual which show a high resistance to tensile stress. As shown in DE 42 21 800, this can be read off from the modulus of elasticity. Materials of polyester are therefore currently a preferred material to be used as the carrier material.

In further processes, the supported gas barrier film is connected to a substrate film by coating processes or lamination processes. The substrate film then takes account of further demands which are made on the total composite film; layer thickness, blow resistance, transparency, mechanical loadability, thermal loadability, weldability, etc. are e.g. demands which are substantially satisfied by the part of the substrate film in a film composite.

Films having a special property profile are in particular in demand for the manufacture of pharmaceutical bags for e.g. infusion solutions. The films of such bags have to be transparent to allow an optical assessment of the solution contained therein; they must remain sterile at temperatures of 121° C.; the film must be blow-resistant and the bag must be able to withstand elevated pressures; and the weld seams have to be able to show corresponding strengths under mechanical effects. Films which can be peelably welded, i.e. films which enter into a semipermanent releasable connection of the films at a reduced welding temperature, are required for the manufacture of multi-chamber bags.

The peelability of a join connection is understood as the connection of two join partners which are releasable without one of the join partners being completely destroyed. In peelable connections of two films, the films are as a rule releasable along their original border surfaces. In special cases in which films are made up of a multilayer composite, peel connections are also understood as a delamination of one of the two films as long as the composite film is not completely broken. Peel connections between films are manufactured by set heat connections or by adhesion promoters. Information on peel connections can be seen from the ASTM standards F88-94 or D 1876-01.

Conventionally, stretched polyester films or stretched polyamide films are used as carrier films for the manufacture of barrier films having ceramic barrier materials. The measure for the stretching of a film is the draw ratio of unstretched film to stretched film. Stretched films can have a draw ratio of 1:10. In longitudinal stretching machines, the longitudinal orientation takes place by draw-off rolls driven at different speeds. In the subsequent lateral stretching, the film is held at both sides by so-called nippers and stretched in its width under the effect of heat. Longitudinally and laterally stretched films are also called biaxially oriented films. Non-stretched films, in contrast, are only minimally stretched by the drawing off of the plastic melt during the extrusion process. Stretched films with a high draw ratio have good mechanical stiffness values as a rule for the coating with ceramic barrier materials. Stretched films are, however, not ideal for all applications from a technical aspect. Stretched polymer materials tend to shrink under the effect of heat. In the sterilization process of solution bags comprising stretched film materials, material changes can therefore occur and may cause a deterioration of the barrier effect. On the other hand, stretched films are thermally relaxed or thermally fixed by a further thermal method step under stress in corresponding plants. On a molecular plane, a relaxation of the polymer chain segments into an entropically favorable state is achieved so that no shrinkage or only minor shrinkage of the material is to be expected on a thermal load of the films. Film materials stretched and thermally fixed in this manner are inter alia also used for the manufacture of heat-sterilizable pharmaceutical solution bags. However, additional methods steps with plant-intensive and energy-intensive installations thus become necessary for the manufacture of stretched films in the manufacture of a gas barrier film.

Furthermore, the commercially manufactured polyester-supported or polyamide-supported ceramic barrier films are produced by a further method step of lamination with a substrate film or top film to form a composite film ready for use. Adhesives and adhesion promoters are distinguished in lamination processes. Adhesives are low-molecular materials which cause adhesion between to laminate layers. Adhesion promoters are understood as high-molecular polymer materials such as are used in extrusion lamination. Modified polymers can e.g. be used as adhesion promoters. Polypropylenes modified with maleinic acid anhydride are e.g. used as adhesion promoters under the trade name “Admer”. Styrenic block copolymers modified by malenic acid anhydride are e.g. known as adhesion promoters under the polymer types “Kraton”. Polymers modified by carboxyl groups, oxazoline groups and glycidyl groups are equally used as adhesion promoters. These high-molecular adhesion promoters are largely inert with respect to migration processes. I.e. the components of this bonding material can largely not be mobilized under application conditions. The migration of components through the composite film to the surface of the film and a subsequent contamination of the packaged good is minimized.

With adhesives in contrast, low-molecular components of the adhesive can migrate through the film composite and can in particular result in unpermitted contaminations of the liquids in contact with the film in medical applications. Adhesives are therefore not unproblematic for use in packaging for pharmaceutical products. From a regulatory aspect, composite films with adhesives are increasingly being viewed critically for the packaging of medicaments.

As a rule, polyester-supported or polyamide-supported ceramic barrier films are laminated with a carrier film by adhesives. The adhesive promotion takes place between the ceramic barrier layer and the carrier film. This type of lamination requires an additional separate process step for building up the gas barrier composite film, which is disadvantageous.

Previous processes for manufacturing ceramic gas barrier films follow a batch process. For this purpose, an already manufactured stretched carrier film is wound on a sleeve to form a film wrap and is introduced into a coating chamber. The carrier film is unwound therein, subjected to a coating process and taken up by a further receiving sleeve to form a film wrap. These processes require a high plant effort and technical process effort. High setup times to prepare and shut down a batch process are disadvantages. For economic considerations, there is then the necessity that film wraps which are as large as possible and have a large surface of the film stored thereon are used for the coating to keep the effort for the setup times low with respect to the quantity of film to be coated. This in turn consequently requires a high technical plant effort since larger coating chambers have to be provided, which makes these processes disadvantageous.

There is thus a need with respect to the prior art to manufacture a ceramic gas barrier composite film for the production of medical solution bags which is free from adhesives or secondary products or degradation products of adhesives and for the manufacture of which the usual lamination methods can be omitted.

It is therefore the object of the present invention to further develop an apparatus, a method, a film as well as a use of an apparatus of the initially named kind in an advantageous manner such that the production of a film can be simplified and the properties of the film can be improved.

A manufacturing process has in particular been sought according to which the use and manufacture of energy-intensive and plant-intensive stretched carrier films for the receiving of the ceramic barrier layer can be dispensed with.

This object is achieved in accordance with the invention by an apparatus having the features of claim 1. Provision is accordingly made that an apparatus for manufacturing an adhesive-free gas barrier film having a preferably ceramic barrier layer includes at least one conveying means for conveying a film web, at least one first lock system for introducing the film web into a coating chamber of the apparatus, at least one first coating means by means of which the film web can be coated at least partially by deposition of a barrier material in the coating chamber, and optionally at least one second lock system for expelling the film web and at least one second coating means by means of which the film web can be coated at least partially by extrusion of a plastic melt and application of the plastic melt onto the film web.

Advantageous embodiments of the apparatus form the subject of the dependent claims.

In this connection, all technical apparatus count as conveying means with which the film web can be led on, deflected, wound up, in particular rollers, deflection rolls and sleeves for winding up the films.

The advantage and the technical effect common to and primary in the invention thus result from the apparatus that an adhesive-free ceramic gas barrier film can be provided while using the process step of extrusion coating, whereby the object underlying the invention is achieved particularly advantageously.

The advantage in particular results that an adhesive-free gas barrier film can be manufactured by means of the apparatus which can reliably prevent a degassing of gas components from e.g. medical solutions from disposables manufactured from the adhesive-free gas barrier film.

Reference is made in this connection to solutions containing bicarbonate which tend to split off carbon dioxide (CO₂). If released carbon dioxide gases out of the dialysis solution, this results in an increase in the pH, which can result in an unwanted precipitation of calcium carbonate (CaCO₃).

In addition to the reliable prevention of a degassing of gas components, it is, however, now also possible by the invention to dispense with adhesive layers which had previously fixed the inorganic, in particular ceramic, barrier layers previously required for the gas barrier function. This is above all particularly advantageous because these adhesive layers can be a source for substances migrating into the dialysis solution. The problem of these potentially migrating substances is particularly advantageously avoided and thus solved by the possibility of dispensing with the adhesive layer.

It is advantageous if the coating takes place at low pressure. The pressure in the coating chamber is in particular lower than in the atmosphere surrounding the apparatus so that the interior of the coating chamber can be called the low-pressure side relative to the atmosphere surrounding the apparatus. The atmosphere surrounding the apparatus can be called the high-pressure side in this respect since it has a higher pressure relative to the pressure present in the coating chamber. Provision is usually made that the pressure of the high-pressure side corresponds to normal atmospheric pressure.

Provision can optionally be made that the second coating means for applying a plastic melt to the film web lie within the coating chamber. In particular, however, in coatings which require a high vacuum for the first coating means, not all plastic melts in accordance with the second coating can be reliably applied to the film web. In addition, in some cases, the technical plant effort for the second coating means inside the coating chamber can be disadvantageously high. It is necessary in such cases that the film web coated with the first coating means is expelled from the coating chamber by a second lock system onto a high-pressure side. On the high-pressure side, the film web can be conveyed by further conveying means such as rollers and deflection rolls to the second coating means so that extruded plastic melt can be applied to the film web.

It has been shown that if the second coating is carried out inline by the second coating means, an aging, i.e. chemical change, of the first coating does not significantly occur. It can thereby be ensured that an adhesion of the second coating layer on the first coating layer is not disadvantageously influenced.

It is advantageously possible that the apparatus has an extrusion nozzle for extruding at least one plastic melt, with the film web being obtained from the plastic melt, and has one or more rollers for conveying the film web obtained from the extruded plastic melt.

Provision can furthermore be made that the film web can be conveyed at a conveying speed of at least 3 m/min, in particular between 30 m/min and 45 m/min, further in particular between 30 and 300 m/min, or up to 240 m/min, or up to 150 m/min and below, in particular to a maximum of 300 m/min, preferably a maximum of up to 60 m/min.

It is furthermore possible that the first and/or the optionally second lock system has at least one roller lock and/or at least one slit lock.

It is furthermore conceivable that a plurality of suction chambers are provided for the first lock system, or optionally for the second lock system, said suction chambers each forming a pressure stage. Suction chambers can each be located between the individual locks. In this respect, at least one or more degassing chambers can be provided after the suction chambers of the first lock system. The advantage results from the degassing chamber that a removal of volatile parts from the film can take place.

Suction chambers located between the individual locks can be equipped with pumping means depending on the vacuum requirement, e.g. a rotary vane pump, a Roots pump or a turbopump.

The vacuum can also be applied stepwise by a plurality of suction stages so that the vacuum arises in the total lock system by a pressure drop from atmospheric pressure to a preferred end pressure of 10⁻⁶ mbar.

Provision is in particular made that a barrier layer can be deposited onto the film web using the coating chamber and the first coating means. There is a need in films for the packaging of pharmaceutical bulk materials that the barrier layer has a barrier effect for the passage of gases such as oxygen, carbon dioxide, water vapor. Exceptional barrier effects can be assigned to inorganic coating materials such as can be achieved by depositing metal or ceramic materials on the film web. In particular aluminum is suitable for a coating by metals. Silicon oxides or aluminum oxides are especially suitable for the deposition of ceramic materials. In an embodiment of the inventive idea, provision is therefore made that the coating chamber has means for depositing a ceramic barrier layer onto the film web.

Provision can furthermore be made that the coating chamber has an ion source for pretreating the carrier film, with it being an ion source of noble gases such as argon and/or reactive gases such as gases of hydrocarbons and unsaturated hydrocarbons, oxygen, nitrogen and gaseous nitrogen compounds, halogens, ammonia, laughing gas, ethylene oxide, etc. An argon-oxygen ion source is preferably selected for a film pretreatment, with in particular one or more ion sources being provided for the pretreatment of the film web. The treatment advantageously takes place from one side of the film, from the coating side. The means for pretreatment of the film are advantageously arranged in the coating chamber. Reactive gases are understood as those gases which are capable of forming chemical compounds with the film material after the ionization. Noble gases can be distinguished from this. Noble gases are admittedly capable in their ionized form of chemically modifying the film material, in particular the surface of the film material; the noble gases themselves are, however, not capable of forming stable chemical compounds with the film material.

In addition, the coating chamber has a coating zone in which one or more ion sources are attached for assisting the deposition of the ceramic barrier material onto the carrier film. An argon/oxygen mixture is preferably made use of to generate ionized gases.

It is furthermore conceivable that at least one deposition material or evaporation material is provided in the coating material for depositing a ceramic barrier layer, e.g. an aluminum oxide layer or a silicon oxide layer. An evaporation material on the basis of silicon and oxygen, in particular a mixture of silicon (Si), silicon suboxides (SiOx) or silicon dioxide (SiO₂) is proffered by means of which Si and/or SiOx can be evaporated and deposited on the film web. An evaporation of a silicon/silicon oxide mixture preferably takes place at a temperature of 1000° C. to 1500° C., 1250° C. to 1500° C., 1200° C.±100° C., 1300° C.±100° C., in particular 1250° C. It is in particular conceivable that a mixture of Si and SiO₂ is used in a mixing ratio of e.g. 50:50 as the starting material for a coating. This mixing ratio can, however, generally be variable and be selected in accordance with the demands. Alternative deposition processes of ceramic barrier materials with which ceramic gas barrier layers can be generated are sputtering, plasma enhanced chemical vapor deposition (PECVD) and physical vapor deposition (PVD).

A mixture of silicon oxides (SiOx) is used as the starting material for preferred deposition processes of ceramic silicon layers, with it applying with respect to the stoichiometric composition of the silicon oxides: SiOx where x=0 to 2; preferably where x=0.5 to 1.7 or x=0.7 to 1.3 or x=0.9±0.2 or x=1.0±0.2 or 1.1±0.2 or x=1.7±0.2. In addition, it is conceivable that substantial portions of elemental Si or SiO₂ are present in the mixture of silicon oxides.

In addition, it is possible that at least one means for measuring the coating thickness and/or at least one cooled coating roller is provided inside or outside the coating chamber, with the cooled coating roller preferably being operable in a temperature range from −70° C. to +70° C.

Provision is in particular advantageously made that the method in accordance with one of the claims 11 to 17 can be carried out and a film having the features of claims 18 to 20 can be manufactured using the apparatus.

The film in accordance with the present invention is preferably manufactured in accordance with a method and/or while using an apparatus in accordance with the present invention. The film in accordance with claim 18 or claim 18 and optionally advantageous embodiments of the film can be manufactured in accordance with a method in accordance with one of the claims 11 to 17 or in accordance with another advantageous aspect of the method and/or in an apparatus in accordance with one of the claims 1 to 10 or in accordance with another advantageous aspect of the apparatus.

The present invention furthermore relates to a method having the features of claim 11. Provision is accordingly made that a method of manufacturing an adhesive-free gas barrier film having a preferably ceramic barrier layer comprises the following steps:
optionally, extruding a plastic melt to form a carrier film;
conveying, in particular inline conveying, of the carrier film to at least one lock system;
introducing the carrier film through the lock system into a coating chamber;
depositing a barrier layer onto the carrier film;
optionally, expelling the film web;
coating, in particular inline coating, i.e. without any interruption of the film conveying, of the preferably ceramic barrier layer by applying a plastic melt, for example after a melt extrusion coating process.

Advantageous embodiments of the method are the subject of the dependent claims.

Provided that the film web is to be coated with the barrier layer in the coating chamber under provided pressure conditions, provision is preferably made that the film web is conveyed from a high-pressure side through the lock system to a low-pressure side of the coating chamber.

A manufacture of a barrier film preferably takes place in the method in accordance with the invention, with the barrier effect taking place by deposition of inorganic, metallic or ceramic barrier materials.

As already described above in detail, the advantage and technical effect common to and primary in the invention also result from the method that an adhesive-free, preferably ceramic gas barrier film can be provided using the process step of extrusion coating.

It is possible that the steps
extruding at least one plastic melt by at least one extrusion nozzle for manufacturing at least one carrier film or one substrate film; and
transporting the extruded film to the coating chamber
   are carried out inline at the start of the method to obtain the carrier film.

Provision can be made that the conveying speed of the film is at least 3 m/min, in particular between 30 m/min to 45 m/min, further in particular between 30 and 300 m/min, or up to 240 m/min, or up to 150 m/min and below, in particular to a maximum of 300 m/min, preferably a maximum of up to 60 m/min.

It is furthermore possible that the first and/or the second lock system has at least one roller lock and/or at least one slit lock.

It is furthermore conceivable that a plurality of suction chambers are provided which each form a pressure stage and/or that at least one degassing chamber is provided after the suction chambers.

The vacuum can also be applied stepwise by a plurality of suction stages so that the vacuum arises in the total lock system by a pressure drop from atmospheric pressure to a preferred end pressure of 10⁻⁶ mbar.

It is furthermore possible that a film pretreatment takes place in the coating chamber by irradiation using at least one ion source, with it being an ion source of noble gases such as argon and/or reactive gases such as gases of hydrocarbons and unsaturated hydrocarbons, oxygen, nitrogen and gaseous nitrogen compounds, e.g. ammonia, laughing gas, halogens, e.g. chlorine, bromine, iodine, fluorine, ethylene oxide, etc. Those gases are to be considered as reactive gases which can form chemical compounds with further reaction partners, in particular with the coating material, under the coating conditions. An argon-oxygen ion source is preferably selected for a film pretreatment, with in particular one or more ion sources being provided for the pretreatment of the film web. The treatment advantageously takes place from one side of the film, from the coating side. The means for pretreatment of the film are advantageously arranged in the coating chamber.

It is furthermore conceivable that, in accordance with the method in accordance with the invention, at least one deposition material is provided in the coating chamber for depositing a ceramic barrier layer, e.g. an aluminum oxide layer or a silicon oxide layer. The selection of an evaporation method in which a mixture of silicon (Si), silicon oxides (SiOx) or silicon dioxide (Si0₂) is evaporated and is deposited on the film web is preferred. An evaporation of a silicon/silicon oxide mixture preferably takes place at a temperature of 1000° C. to 1500° C., 1250° C. to 1500° C., 1200° C.±100° C., 1300° C.±100° C., in particular 1250° C. It is in particular conceivable that a mixture of Si and SiO₂ is used in a mixing ratio of e.g. 50:50 as the starting material for a coating. This mixing ratio can, however, generally be variable and be selected in accordance with the demands. Equally, alternative processes can be used for depositing a ceramic barrier material onto a plastic carrier film. Sputtering, plasma enhanced chemical vapor deposition (PECVD) or physical vapor deposition (PVD) can e.g. be named as alternative processes.

Provision can be made that a measurement of the coating thickness takes place in the coating chamber. A cooling of the film web preferably takes place by cooling rollers, in particular in that the coating roller is set to a temperature in a temperature range from −70° C. to +70° C.

The present invention furthermore relates to a film having the features of claim 18. Provision is accordingly made that a multilayer gas barrier film includes a carrier layer of a monolayer or multilayer design, preferably a carrier film comprising one or more thermoplastic materials, selected from the group of polyolefins, polyesters, polyamides or thermoplastic elastomers (TPE), thermoplastically elastomer polyurethanes (TPU) and thermoplastic polyolefins (TPO). A ceramic barrier layer is arranged thereon, in contact with a further unstretched monolayer or multilayer top layer of plastic materials selected from the group of polyolefins, polyesters, polyamides or thermoplastic elastomers (TPE) without an adhesive layer being arranged between the top layer and the barrier layer.

The group of thermoplastic elastomers in this respect includes styrene block copolymers or thermoplastic polyolefins (TPO), elastomer polymers of polypropylene (PP), polyethylene (PE), polybutylene (PBU) and polyalphaolefins. Polyalphaolefins include polymers which are e.g. made up of monomers of butene, pentene, hexene, heptene, octene or dodecane.

In this respect, a starting film onto which the deposition of the ceramic barrier materials takes place is understood as the carrier layer or carrier film. In this respect, a film layer which covers the generated layer of the ceramic barrier materials is understood as the top layer or top film. The carrier layer and the top layer can be designed identically or differently, with no restriction standing in the way of the functional alignment of the carrier layer or top layer in the sense of the invention. The designation of carrier layer and top layer is made to make the sequence of the individual layers in a finished composite film distinguishable in accordance with the procedure in the manufacture.

The advantage and the technical effect common to and primary in the invention also result from the film, namely that the adhesive-free ceramic gas barrier film can itself be provided, with this film in accordance with the invention being provided while using the process step of extrusion coating.

It is advantageously conceivable that the carrier layer amounts to 10 to 300 μm, in particular 20 to 250 μm, 10 to 100 μm, preferably 30-100 μm or 30-80 μm and/or that the gas barrier layer is a ceramic layer comprising silicon suboxides (SiOx), in particular a silicon suboxide SiOx where x=1.2 to 1.9 or 1.3 to 1.8 or 1.4 to 1.7, in particular 1.7, or is aluminum oxides (AlOx) and has a thickness of 10 to 500 nm, 30 to 300 nm, 15 to 150 nm, in particular 30 to 100 nm, preferably 50 nm.

It is in particular advantageously a multilayer gas barrier film which was manufactured by means of an apparatus in accordance with one of the claims 1 to 10 and/or by means of a method in accordance with one of the claims 11 to 17.

The film in particular includes a carrier layer and a top layer which are based on polyolefin materials and thermoplastic elastomers. Polyolefin materials are to be understood as plastics which are made up of polymers which include olefinic monomers. Polymers which are made up of alpha-olefins such as propylene, ethylene, butylene, hexene, octene and further terminally unsaturated olefins are called polyalphaolefins. In particular copolymers of the named monomers, blends of the polymers resulting therefrom, block copolymers of the named monomers and blends of the block copolymers and polymers resulting therefrom, branched polymers of the named polymers and blends comprising the polymers, copolymers, block copolymers and branched polymers manufactured from the monomers are understood under the term.

Individual layers can likewise be made up of other thermoplastic materials such as polyester or polyamides.

The carrier film or the top film or layers of these films can furthermore include thermoplastic elastomers of acrylic block copolymers. Such polymers are made up in block manner by polymer-chemical duplication units of styrene, propylene, butylene, ethylene, isoprene, butadiene and include e.g. styrene ethylene butylene block copolymers (SEBS, SEB), styrene isoprene block copolymers (SIS), styrene ethylene propylene block copolymers (SEPS, SEEPS). Exemplary layer designs are described e.g. in EP 0 739 713.

The present invention furthermore relates to a use of the apparatus for manufacturing an adhesive-free gas barrier film having the features of claim 21. Provision is accordingly made that the apparatus in accordance with one of the claims 1 to 10 is used for carrying out a method in accordance with one of the claims 11 to 17, in particular for manufacturing a multilayer gas barrier film in accordance with one of the claims 18 to 20.

The present invention furthermore relates to a disposable having the features of claim 22. Provision is accordingly made that the apparatus in accordance with one of the claims 1 to 10 is used for carrying out a method in accordance with one of the claims 11 to 17, in particular for manufacturing a multilayer gas barrier film in accordance with one of the claims 18 to 20.

The disposable can in particular be a film bag for single use which is preferably provided for the receiving of medical solutions.

Further details and advantages of the invention will now be explained in more detail with reference to an embodiment shown in the drawing.

There are shown

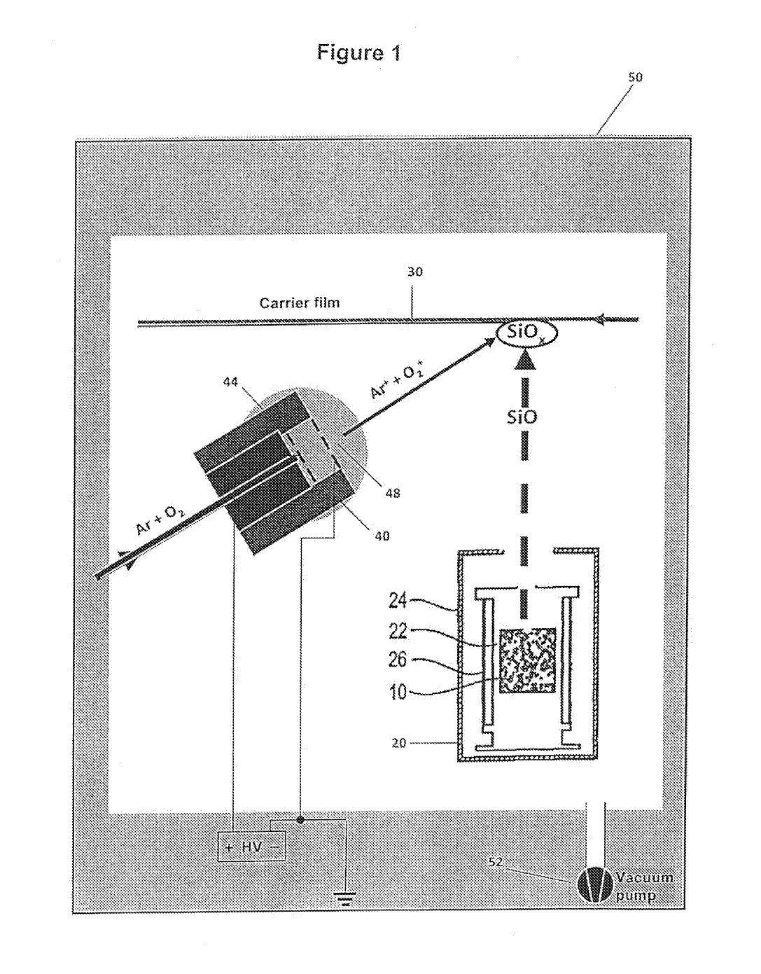

FIG. 1: a schematic representation of the combination method for coating carrier films with an SiOx barrier; and

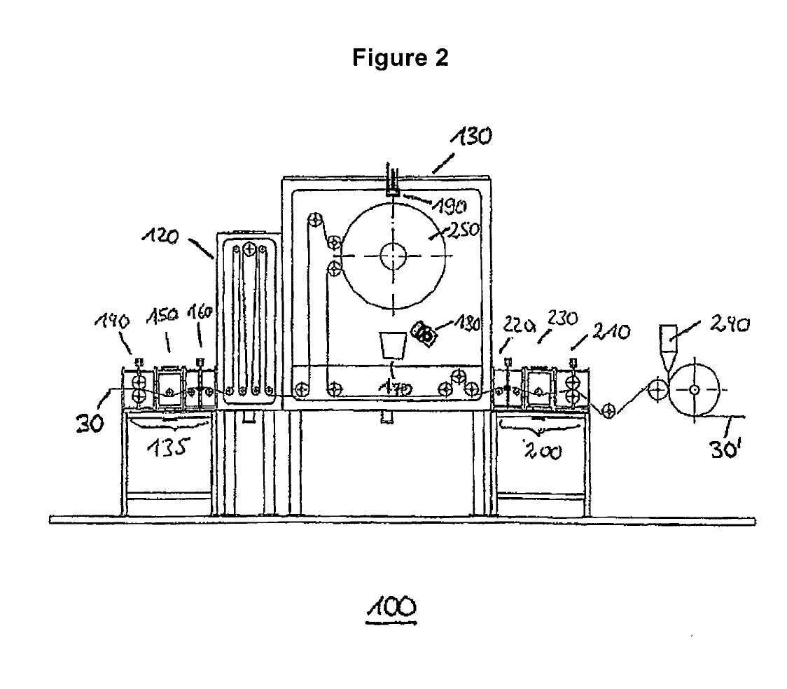

FIG. 2: a schematic representation of the apparatus in accordance with the invention for manufacturing an adhesive-free gas barrier film having a ceramic barrier layer; and

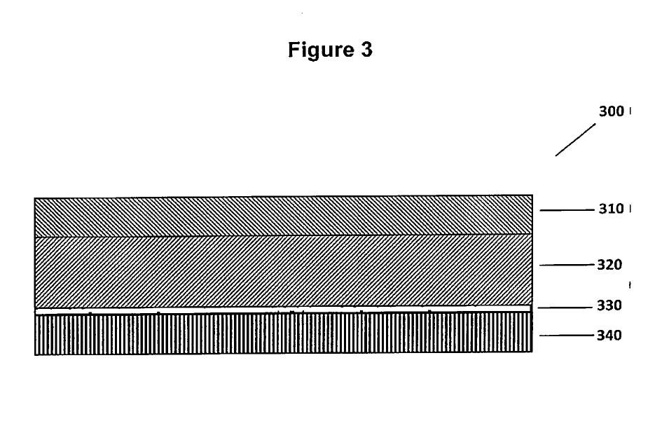

FIG. 3: a schematic representation of a design of an adhesive-free composite film in accordance with the invention.

FIG. 1 shows, in a schematic representation, the combination method for coating film webs, hereinafter carrier films, with an SiOx barrier.

The starting material silicon monoxide (SiO), which is present as SiO granulate 10 in a mixture with further silicon oxide compounds, is heated in a crucible 22 surrounded by a radiation protector 24 by means of a heating wire 26 in high vacuum to temperatures of 1300-1500° C. at which it changes in a sufficient quantity into the gas phase. The vapor is deposited on the carrier film 30 led past above the evaporation furnace 20. The barrier of the SiOx layers thus generated is, however, not yet sufficient.

Sufficiently low gas permeabilities are achieved in combination with an ion source 40 (IBAD: ion-beam assisted deposition). For this purpose, the silicon suboxide, e.g. SiO_{1,4} condensing on the carrier film is bombarded with ionized particles. This results in a denser SiOx layer with fewer defect points.

The ion source 40 which is e.g. an argon-oxygen ion source 40 has a high-voltage supply HV and a heating not designated in more detail. The ion source 40 furthermore has an anode 44. In this respect, Ar⁺ and O₂⁺ are representative for any ionized species which can be formed from the reactive gas. The total procedure takes place in a vacuum chamber 50 at a pressure of p=1*10⁻⁴ to 1*10⁻⁷ mbar. The vacuum is applied by the vacuum pump 52.

FIG. 2 shows, in a schematic representation, the apparatus 100 in accordance with the invention for manufacturing an adhesive-free gas barrier film having a ceramic barrier layer.

The carrier film 30 is in this respect introduced into the coating chamber 130 through the lock unit 135 and the degassing chamber 120. A suction module 150 is provided downstream of the lock module 140 and is followed by a further slit lock module 60 to reach the required process pressure. After running through a degassing chamber 120, the film moves into the coating chamber 130, where the SiOx barrier layer is vapor deposited. The SiOx vapor is generated by an evaporation furnace 170 in the coating chamber 130.

The SiOx layer is applied in association with the IBAD ion source 180. In addition, a pretreatment of the film is provided via an ion source 190 in which the surface is activated for subsequent process steps. A measurement of the film tension takes place by means of a film tension measuring device and a measurement of the layer thickness by means of a layer thickness measuring device.

A good contact to the cooling roller is indispensable to avoid a thermal overstraining of the carrier film since the process steps in the coating chamber are associated with a high heat development such that the carrier film can be destroyed. A cooling roller temperature from −50° C. to +50° C. is set in dependence on the thickness of the film 30. Finally, the coated film 30′ is again expelled from the coating plant 100 via the lock modules 220, 210 and the suction chamber 230 of the lock unit 200.

The second coating means, by means of which the film web can be at least partially coated by melt extrusion, is arranged after the lock unit 200 and is shown schematically. An extrusion tool 240 in this respect applies a plastic melt onto the transported film web 30′ and thus coats the just produced SiOx layer in an inline process, i.e. without process interruption and within the ongoing process.

In accordance with the principle, the manufacture of a ceramic gas barrier composite film thus essentially takes place by
the extrusion of a monolayer/multilayer carrier film;
the introduction of the film web into a coating plant by a vacuum lock system;
the coating of the film using ion beam assisted deposition—IBAD—of a ceramic material;
the expulsion of the film by a vacuum lock system; and
coating the composite film with a monolayer/multilayer top layer by melt extrusion.

It has been shown that adhesive can be dispensed with in accordance with this method. It is decisive that the ceramic coating comes into connection with the top layer in real time so that aging processes of the ceramic surface do not come into play. The non-aged surface in this respect enters into a good connection with the melt-extruded top layer. In contrast to the subject matter of EP 0 640 474, in particular the great advantage results that the application of the top layer does not have to take place in a vacuum. It is sufficient for the adhesion between the ceramic surface and the top layer that the ceramically coated carrier film and the top layer are connected inline outside the vacuum chamber. The total manufacturing process of the gas barrier film composite can thus be carried out in an inline process.

In the simplest case, the carrier film is only provided as a mechanical support for the gas barrier film. In alternative cases, the carrier layer can be of a functional design and take over essential requirements of the total composite film with respect to mechanical stability, optical quality and thermal properties which are required for the manufacture of solution bags.

It may be necessary that the carrier film is present in a thermally largely stable state, i.e. that the polymer materials may not be subject to any process of postcrystallization after extrusion. A postcrystallization of the used plastic materials after the coating with the ceramic barrier material can cause defective points in the barrier layer by material tensions. Temperature setting processes therefore take place after the extrusion of the carrier film so that possible crystallization processes can take place within the film before the deposition of the ceramic barrier material takes place.

In the simplest case, the top layer can only serve as a protective layer for the ceramic gas barrier layer. In alternative cases, the top layer can itself already be functionally designed for the manufacture of bag films and can take over mechanical, thermal and optical demands on the total composite film.

It is possible that the carrier layers and/or top layers are monolayer or multilayer, depending on the function of the total composite film.

Polyolefins, polyalphaolefins of ethylene, propylene, butylene, hexene, octene, etc., polypropylene, polyethylene, SEBS, SIS, SEPS, SEP, in alternative cases also polyesters (PET) or polyamides (PA), can be selected as materials for the carrier film and top film.

In the present method in accordance with the invention, a stable composite film is obtained directly by carrier film, barrier layer and top layer through the inline method. On the one hand, stretched carrier films can thus be dispensed with; on the other hand, the resulting composite film can be further used directly for the production of solution bags without further lamination processes to be provided.

The thickness of the carrier film and/or of the top film can amount, for example, to 10 μm, but also up to 300 μm for bag films. All thickness values between 10 μm and up to 300 μm can naturally be selected depending on the application. In particular a value between 20 and 250 μm, or 10 and 50 μm, preferably 30 μm, is selected as the thickness value.

It is advantageously conceivable that the carrier layer amounts to 10 to 300 μm, in particular 20 to 250 μm, 10 to 100 μm, preferably 30-100 μm or 30-80 μm and/or that the gas barrier layer is a ceramic layer comprising silicon suboxides (SiOx), in particular a silicon suboxide SiOx where x=1.2 to 1.9 or 1.3 to 1.8 or 1.4 to 1.7, in particular 1.7, or aluminum oxides (AlOx) and has a thickness of 10 to 500 nm, 30 to 300 nm, 15 to 150 nm, in particular 30 to 100 nm, preferably 50 nm.

A ceramic coating is in principle possible on both sides of the carrier film.

FIG. 3 shows a schematic design of a film 300 in accordance with the invention. The carrier film 340 is of monolayer design in the present example. In the course of the process, the carrier film 340 is introduced into a coating chamber via the lock system and is coated with a ceramic gas barrier material which forms into a dense layer 330. In the present case, the layer 330 is exemplary for a silicon oxide layer which was manufactured by an IBAD assisted gas deposition process. After expelling the coated carrier film from the coating chamber, the top layer is applied by melt extrusion coating. For this purpose, an extrusion melt, which is already prepressed in two layers, is applied to the carrier film; they form the tops layers 320 and 310.

In the present exemplary embodiment, the top layer is designed as two-layer, with the one layer satisfying predefined demands on the weldability of the composite film.

In this respect, the substantial demands on the total composite film with respect to mechanical stability, e.g. blow resistance, are satisfied via the layer 320 which overcoats the ceramic barrier layer 330 as the top layer.

The layer 310 is designed so that the total composite film can be welded; it can in particular also be welded in a peelable manner. The layer 310 is also called a 5sealing layer in this connection.

The carrier layer 340 has to deliver a stiff basis for the barrier layer 330. The composite film is thereby characterized with respect to a high tear propagation resistance, a high piercing resistance and a low stretching under tensile strain. It is furthermore advantageous if there is a low tendency to interlocking of the composite film, e.g. in the construction of a solution bag, over the carrier film. An interlocking tendency is here understood as the behavior of films to adhere to smooth surfaces under the effect of pressure.

Alternatively, an adhesion promoter layer not shown in FIG. 3 can also be arranged between the barrier layer 330 and the top layer 320. Adhesion promoter layers which are applied by extrusion coating are widely known.

The carrier layer 340 and the sealing layer 310 form outer layers of the composite film. In a solution bag manufactured from the film 300, the sealing layer 310 forms a side facing the bag content. The carrier layer 340 forms the outer side in such a bag.

An exemplary design of a film in accordance with the invention which is free of adhesives shows the following structure:
Carrier layer (340):
Layer thickness: 30 μm
Formulation: 100% Homo polypropylene HD 601 CF Borealis
Barrier layer (330):
Layer thickness: 50 nm
Formulation: SiO_{1.7±0.2}
Top layer (220):
Layer thickness: 130 μm
Formulation: 70% Random copolymer of polypropylene RD 204 CF Borealis 30% SEBS Kraton G 1652
Sealing layer (210):
Layer thickness: 20 μm
Formulation: 80% Random copolymer of polypropylene RD 204 CF Borealis 20% SEBS Kraton G 1652

The composite layer named by way of example delivers a ready-to-use gas barrier film which can e.g. be used in packaging means of foods or pharmaceuticals.

The apparatus shown in FIG. 2 can also be advantageously designed as follows:

The lock module can have a roller lock 140 in which the film is led between rollers and is sealed at the sides. It is not absolutely necessary that a pressing takes place between the rollers.

A slit lock 160 as shown schematically in FIG. 2 is furthermore provided. The film is in this respect led through a narrow gap between two metal plates. The advantage results that there are no moving parts of the lock which require a complex sealing.

Subsequently, the film runs through a degassing chamber 120 in which volatile components are separated from the film. A longer dwell time of the film in the degassing chamber is desired so that volatile substances encapsulated, dissolved or adsorbed in or at the composite film can escape.

Provision can be made for the setting of the dwell time of the films that 6 meters of film (variable depending on the plant) are led through the degassing chamber. The dwell time of the film through the degassing chamber depends on the possible film conveying speed. The conveying speed of the film is in this respect at least 3 m/min, in particular between 30 m/min and 45 m/min, further in particular between 30 and 300 m/min, or up to 240 m/min, or up to 150 m/min and below, in particular to a maximum of 300 m/min, preferably a maximum of up to 60 m/min.

A film pretreatment takes place in the coating chamber. In this respect, the film is irradiated by means of an ion source (argon, oxygen and/or further gases as already named) and the formation of plasma is brought about. A cleaning and surface activation of the carrier film to be coated hereby takes place.

Furthermore, a means for measuring the coating thickness is provided for quality assurance and online inspection. Around 50 nm is selected as a usual layer thickness for an SiOx layer. It is generally possible that a thickness from 30 to 300 nm, in particular 30 to 100 nm, or 10 to 300 nm, preferably 15 to 150 nm, preferentially 50 nm, is selected.

The starting material for the coating with silicon oxides is preferably a mixture of Si and SiO₂, e.g. in a ratio of 50:50 and/or in a mixture with SiOx. The following applies preferably with respect to SiOx: SiOx where x=0 to 2; preferably where x=0.5 to 1.7 or x=0.7 to 1.3 or x=0.9±0.2 or x=1.0±0.2 or 1.1±0.2 or x=1.7±0.2. In the finished ceramic barrier layer, SiOx is preferably present in a stoichiometry of SiO_{1.7±2.}

It must be noted with respect to the layer thickness that too thin a layer is admittedly flexible, but has poor barrier values, whereas too thick a layer brings about a good barrier effect, but brittle material properties, that is there is a risk of a crack formation in the barrier layer.

The Si/SiOₓ is evaporated and is deposited on the film. The temperature amounts to 1250° C. to 1500° C. in this respect. It is generally possible that the deposition takes place at a temperature of 1000° C. to 1500° C., 1250° C. to 1500° C., 1200° C.±100° C., 1300° C.±100° C., in particular 1250° C.

The spacing of nozzle to film in this respect amounts to 100 mm to 350 mm. The risk of film melting is to be considered and prevented. There is a small risk of melting due to a faster film transport since hereby the film cannot reach its melting temperature during the exposure in the coating zone.

It is conceivable that the coating roller is cooled and can in this respect be operated in a temperature range from −70° C. to +70° C.

The coating layer on the carrier film is irradiated by means of the IBAD source, with the IBAD ion source utilizing argon and oxygen. A compacting of the SiOₓ layer and a stoichiometric modification of the silicon oxide take place by the IBAD ion source. An advantageous stoichiometric composition of the silicon oxide with respect to thermodynamic stability, optical transparency and fluid-tightness is SiO_{1.2-1.9.}

A preferred barrier effect for films which are used for solutions containing bicarbonate should at least have a permeability for CO₂ of at most

$$Permeability \leq 20 \frac{{cm}^{3} ( {CO}_{2} )}{bar * {m}^{2} * 24 h} ; preferably \leq 10 ;$$

$$further preferably \leq 5 ;$$

$$furthermore preferably \leq 1 ,$$

depending on the concentration content of the bicarbonate in solution and on the partial pressure of the CO₂ then in equilibrium. Methods for the permeability determination of films are documented by standards. In particular suitable are e.g. ASTM D1434 or DIN 53380.

In the sense of the invention, the barrier films in accordance with the invention have values of gas permeability of preferably less than 20 ml(CO₂)/bar/m²/24 h or 10 ml(CO₂)/bar/m²/24 h, or 5 ml(CO₂)/bar/m²/24 h. Corresponding permeability values which correlate in a known manner with the permeability values of oxygen apply to the oxygen barrier for barrier film in accordance with the invention.

1-10. (canceled)

11. A method of manufacturing an adhesive-free gas barrier film comprising the steps:
optionally, extruding a plastic melt to form a carrier film;
conveying, in particular inline conveying, of a carrier film (30) to at least one lock system (135);
introducing the carrier film (30) through the lock system (135) into a coating chamber (130);
depositing a barrier layer onto the carrier film (30);
optionally, expelling the film (30) through a lock system (200); and
coating, in particular inline coating, of the barrier layer by applying a plastic melt.

12. A method in accordance with claim 11, characterized in that the steps
extruding at least one plastic melt through at least one extrusion nozzle for manufacturing at least one carrier film (30); and
conveying the obtained extruded film to the coating chamber, are carried out inline at the start of the method to obtain the carrier film (30).

13. A method in accordance with claim 11 characterized in that the conveying speed of the film amounts to at least 3 m/min, in particular between 30 m/min and 45 m/min, further in particular between 30 and 300 m/min, or up to 240 m/min, or up to 150 m/min and below, in particular to a maximum of 300 m/min, preferably to a maximum of up to 60 m/min.

14. A method in accordance with claim 11, characterized in that one or more suction chambers (115) are provided which each form a pressure stage; and in that at least one degassing chamber (120) is provided after the suction chambers (115).

15. A method in accordance with claim 11, characterized in that a film pretreatment takes place in the coating chamber (130) by irradiation with at least one ion source, with it preferably being an ion source of noble gases and/or reactive gases, in particular an ion source of argon and oxygen, and/or with the coating chamber (130) having a coating zone in which one or more ion sources (180) are arranged by means of which the film, web (30) is treated, with it preferably being an ion source of noble gases and/or reactive gases, in particular an ion source of argon and oxygen.

16. A method in accordance with claim 11, characterized in that evaporation material based on silicon and oxygen, in particular Si and/or SiOx, is evaporated in the coating chamber (130) and is deposited on the film web, and with further preferably the deposition taking place at a temperature of 1000° C. to 1500° C. or 1250° C. to 1500° C. or 1200° C.±100° C., or 1300° C.±100° C., in particular 1250° C.

17. A method in accordance with claim 11, wherein a cooling of the film web preferably takes place by a cooling roller in a temperature range from −70° C. to +70° C.

18-22. (canceled)
